(19) United States
(12) Patent Application Publication
(10) Pub. No.: US 2011/0170247 A1
(43) Pub. Date: Jul. 14, 2011

(54) Digital utility apparatus and method

(76) Inventor: Stephen Fried, Las Vegas, NV (US)

(21) Appl. No.: 12/927,969

(22) Filed: Nov. 30, 2010

Related U.S. Application Data
(60) Provisional application No. 61/265,202, filed on Nov. 30, 2009.

(51) Int. Cl. H05K 7/00; E04B 1/35

(52) U.S. Cl. 361/679.01; 52/741.1

(57) ABSTRACT

A method and apparatus for a digital utility system. The system may include a housing secured within a wall and partially exposed through an opening in the wall covering. A processing unit may be inserted into the housing (and into the wall) through the opening. Various systems of a building may be connected to the processing unit to receive commands and the like therefrom. A user interface and monitor may connect to the processing unit and extend to cover the opening in the wall covering.

### BACKGROUND

1. The Field of the Invention

This invention relates to digital systems and, more particularly, to novel systems and methods for space-saving, multimedia networks.

2. The Background Art

Consumer entertainment spending, including products and services, increased dramatically from 2003 to the present and is projected to continue in a steep upward direction for years to come. Similarly, more and more individuals are using computers as a form of entertainment. For example, computers are used to access the Internet, play video games, play music and burn compact discs (CDs). Unfortunately, access to all of the desired entertainment applications often requires numerous hardware and software systems to be purchased and installed in a residential or commercial facility. Accordingly, equipment tends to be positioned throughout the subject facility such that use, access, and maintenance can become problematic. Moreover, compatibility of the equipment is always a concern as well.

Current multi-media systems can occupy large amounts of space. With current real estate prices, it is not seemingly desirable to utilize too much floor space on unsightly hardware components. Security is also an issue for any multi-media system connecting to the Internet.

Thus, there is a need for a multi-media system suitable for residential and commercial use that is self-contained, occupies little floor space, and provides reliable security.

### SUMMARY OF THE INVENTION

In view of the foregoing, in accordance with the invention as embodied and broadly described herein, a method and apparatus are disclosed in one embodiment of the present invention as including a housing secured within a wall and partially exposed through an opening in the wall covering. A processing unit may be inserted into the housing (and into the wall) through the opening. Various systems of a building may be connected to the processing unit to receive commands and the like therefrom. A user interface and monitor may connect to the processing unit and extend to cover the opening in the wall covering.

### BRIEF DESCRIPTION OF THE DRAWINGS

The features of the present invention will become more fully apparent from the following description, taken in conjunction with the accompanying drawings. Understanding that these drawings depict only typical embodiments of the invention and are, therefore, not to be considered limiting of its scope, the invention will be described with additional specificity and detail through use of the accompanying drawings in which:

FIG. 1 is a front perspective view of a system in accordance with the present invention installed within a wall;

FIG. 2 is a front perspective view of a system 10 in accordance with the present invention;

FIG. 3 is a front perspective view of a monitor and user interface in accordance with the present invention;

FIG. 4 is a rear perspective view of a monitor and user interface in accordance with the present invention;

FIG. 5 is a rear perspective view of a monitor and user interface in accordance with the present invention with the mounting plates removed to expose the under workings thereof;

FIG. 6 is a rear perspective view showing a monitor in accordance with the present invention with the back cover and extension mechanism removed;

FIG. 7 is a rear perspective view of a screen and mounting rim in accordance with the present invention;

FIG. 8 is a front perspective view of a cover of one embodiment of a user interface in accordance with the present invention;

FIG. 9 is a front perspective view of a mounting board for a user interface in accordance with the present invention and the cover of FIG. 8;

FIG. 10 is a front perspective view of a housing with a processing unit in an installed position in accordance with the present invention;

FIG. 11 is a front perspective view of a housing in accordance with the present invention;

FIG. 12 is a front perspective view of a top section of a housing in accordance with the present invention;

FIG. 13 is a front perspective view of an intermediate section of a housing in accordance with the present invention;

FIG. 14 is a front perspective view of a lower section of a housing in accordance with the present invention;

FIG. 15 is a front perspective view of a ventilation section of a housing in accordance with the present invention;

FIG. 16 is another perspective view of the ventilation section illustrated in FIG. 15;

FIG. 17 is a front perspective view of the ventilation section of FIG. 15 with the ventilation cover removed;

FIG. 18 is another front perspective view of the ventilation section of FIG. 17;

FIG. 19 is a front perspective view of a processing unit in accordance with the present invention with the top and bottom halves vertically aligned in an installed position;

FIG. 20 is a perspective view showing the ports on the upper end of the processing unit illustrated in FIG. 19;

FIG. 21 is a front perspective view of a processing unit in accordance with the present invention with the cover removed, exposing the internal components to view;

FIG. 22 is a perspective view showing a bottom end of the processing unit illustrated in FIG. 21;

FIG. 23 is a perspective view of a first half of a case in accordance with the present invention with the cover removed;

FIG. 24 is front perspective view of the upper and lower halves of a case in accordance with the present invention with the internal components removed;

FIG. 25 is a front perspective view of a mounting plate providing the interface between the sections of a housing and monitor and user interface units;

FIG. 26 is a front perspective view of a housing comprising an upper section, two intermediate sections, a lower section, and a ventilation section installed in accordance with the present invention between adjacent vertical studs of an unfinished wall;

FIG. 27 is front perspective view of the housing and studs of FIG. 26 with a wall covering applied thereto;

FIG. 28 is a front perspective view of the wall covering and housing of FIG. 27, with the processing unit and ventilation cover installed in accordance with the present invention;

FIG. 29 is a front perspective view of the devices illustrated in FIG. 28, with a mounting plate installed therein in accordance with the present invention;

FIG. 30 is a front perspective view of the devices of FIG. 29 with a user interface installed therein in accordance with the present invention;

FIG. 31 is a diagram illustrating the various hardware and/or software components that may be supported by a system in accordance with the present invention; and

FIG. 32 is a schematic diagram illustrating one embodiment of the functionality and connections of a system in accordance with the present invention installed in a hotel environment.

### DETAILED DESCRIPTION OF SELECTED EMBODIMENTS

It will be readily understood that the components of the present invention, as generally described and illustrated in the drawings herein, could be arranged and designed in a wide variety of different configurations. Thus, the following more detailed description of the embodiments of the system and method of the present invention, as represented in the drawings, is not intended to limit the scope of the invention, but is merely representative of various embodiments of the invention. The illustrated embodiments of the invention will be best understood by reference to the drawings, wherein like parts are designated by like numerals throughout.

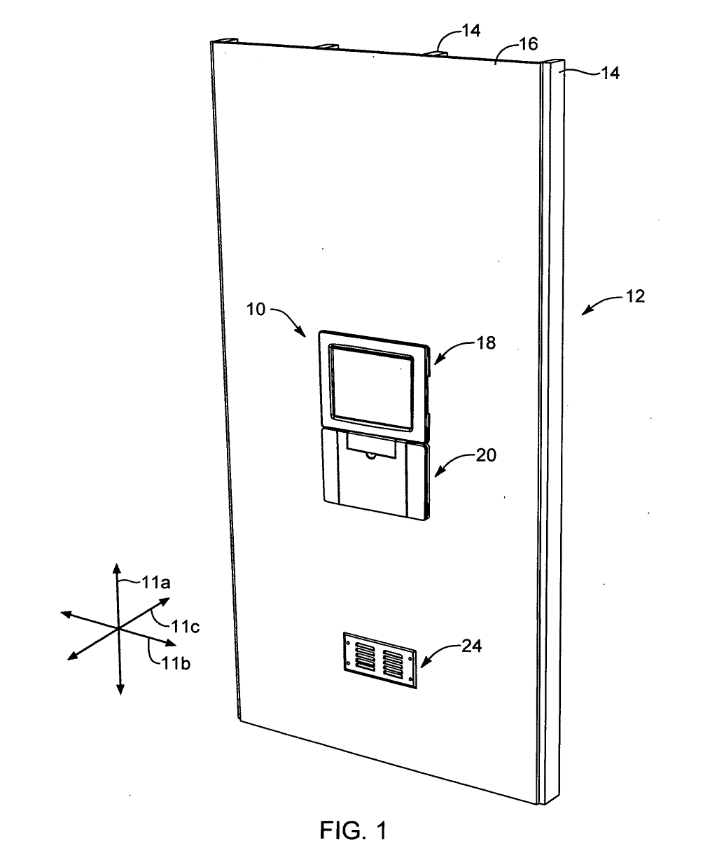

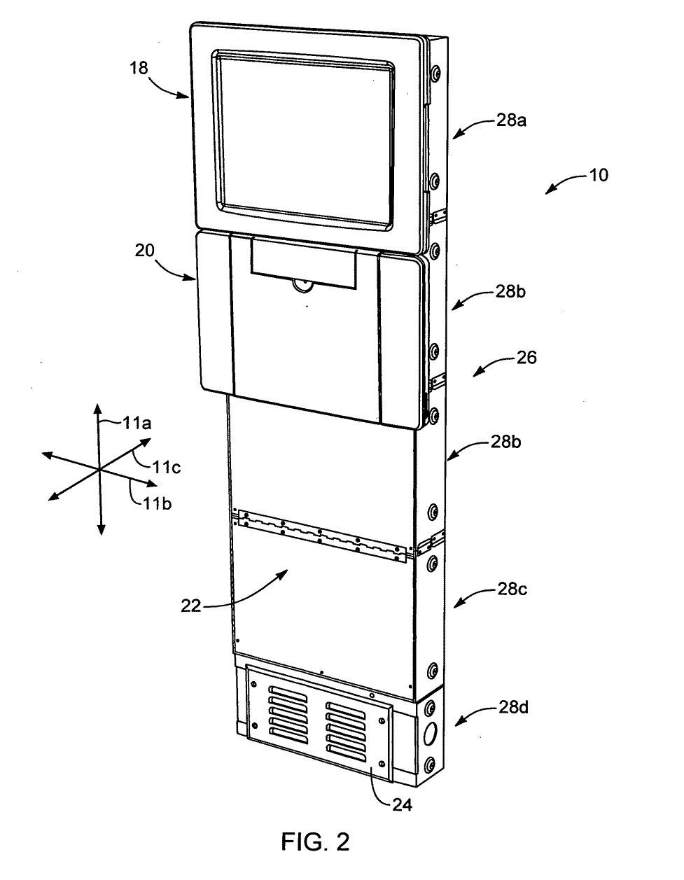

Referring to FIGS. 1 and 2, in describing the various features of the embodiments of a system 10 in accordance with the present invention, it may be desirable to define a coordinate system 11. Accordingly, a coordinate system 11 may be defined by a longitudinal direction 11a, a lateral direction 11b, and a transverse direction 11c. The longitudinal direction 11a, lateral direction 11b, and transverse direction 11c may be mutually orthogonal to one another.

A system 10 in accordance with the present invention may be mounted in a wall 12. In selected embodiments, a wall 12 may be formed of multiple vertical studs 14 and a covering material 16 (e.g., drywall 16). Portions of a system 10 visible outside the covering 16 may include a monitor 18, a user interface 20, and a vent 24.

Positioned behind a wall covering 16 may be a housing 26. A housing 26 may provide the interface between the various components of a system 10 and a wall 12. In selected embodiments, a housing 26 may include various sections 28. For example, in one embodiment, a housing 26 may include a top section 28a, one or more intermediate sections 28b, a lower section 28c, and a ventilation section 28d. In one embodiment, in an installed position, a processing unit 22 may be stored primarily within one or more intermediate segments 28b and the lower segment or section 28c. A processing unit 22 in accordance with a present invention may provide the computational hardware and software of a system 10 in accordance with the present invention.

A system 10 in accordance with the present invention may be connected to various systems within a building. For example, in selected embodiments, a system 10 may be connected to lighting systems, HVAC systems, energy management systems, entertainment systems, security systems, broadband access systems, and the like. In certain embodiments, a system 10 in accordance with the present invention may control, monitor, or control and monitor one or more of the building systems connected thereto. The flexibility of the software and hardware that may be used in a system 10 (e.g., processing unit 22) in accordance with the present invention may result in consolidation and simplification, while bringing significant computer power to bear.

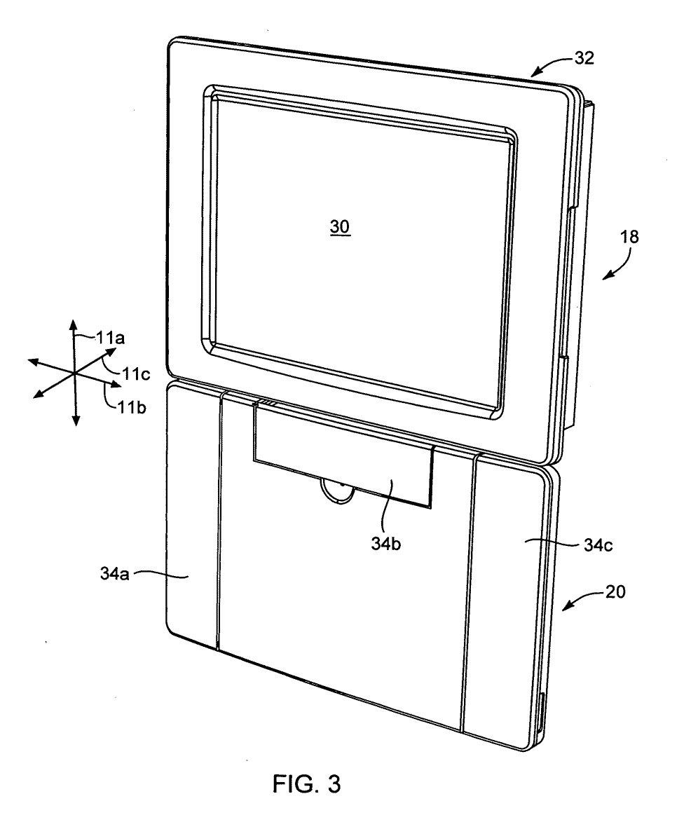

Referring to FIGS. 3-7, a monitor 18 in accordance with the present invention may include a screen 30 and a bezel 32 or outer rim 32. A screen 30 in accordance with the present invention may have any suitable design. In selected embodiments, a screen 30 may be a LCD screen.

In certain embodiments, a user interface 20 may be positioned below a monitor 18. In other embodiments, various aspects of a user interface 20 may be incorporated within the bezel 32 of a monitor 18. In the illustrated embodiment, a user interface 20 includes multiple doors 34. The various doors 34 may provide access to various control features, ports, etc. located therebehind. In the illustrated embodiment, a first door 34a is positioned along a left edge of the user interface 20 as shown in FIG. 3. A second door 34b for a storage compartment is located in the upper, central portion of the user interface 20. A third door 34c is positioned on a right edge of the user interface 20.

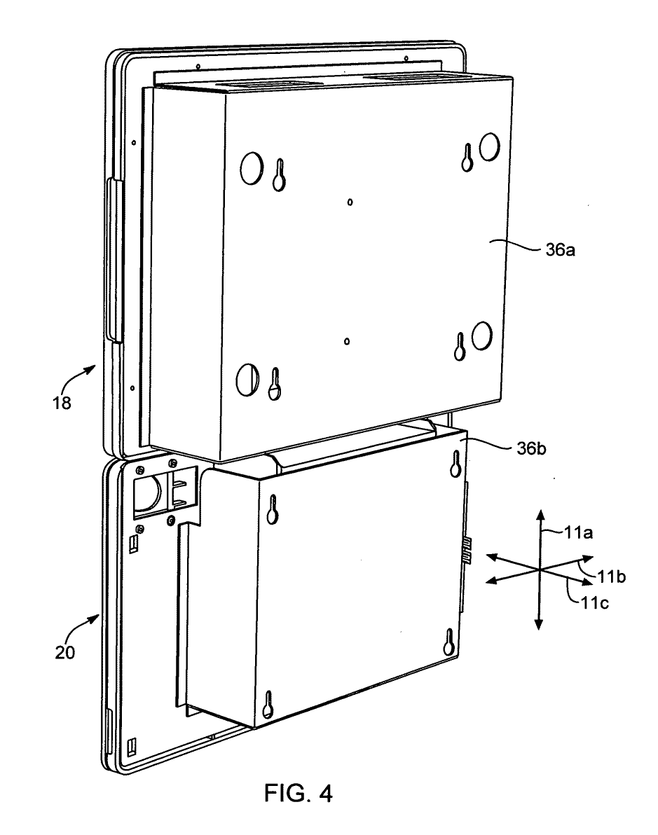

A monitor 18, user interface 20, or some combination thereof, may include one or more mounting brackets 36 as shown in FIG. 4. In the illustrated embodiment, a first mounting bracket 36a may secure a monitor 18, while a second mounting bracket 36b may secure a user interface 20 to a housing 26.

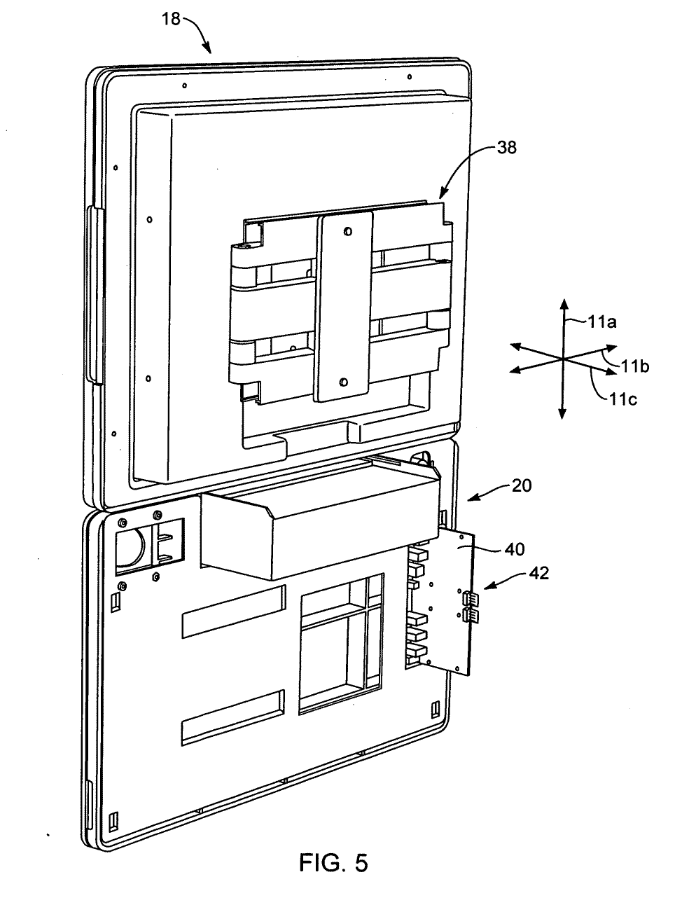

In selected embodiments, an extension mechanism 38 may connect a monitor 30 to a mounting bracket 36a as shown in FIG. 5. An extension mechanism 38 may allow a monitor 30 to be positioned in a particular position as desired by a user. That is, an extension mechanism 38 may permit a user to pull a monitor 30 transversely 11c away from a wall covering 16. Similarly an extension mechanism 38 may permit a user to shift a monitor 30 laterally 11b, vertically 11a, etc.

In selected embodiments, a user interface 20 may include one or more electrical components communicating information or making connections between a user and a processing unit 22. For example, in the illustrated embodiment shown in FIG. 5, a circuit board 40 is illustrated in relation to the user interface 20. The circuit board may include multiple ports and various electrical connectors suitable for communicating information or data or commands from the user interface 20 to a processing unit 22.

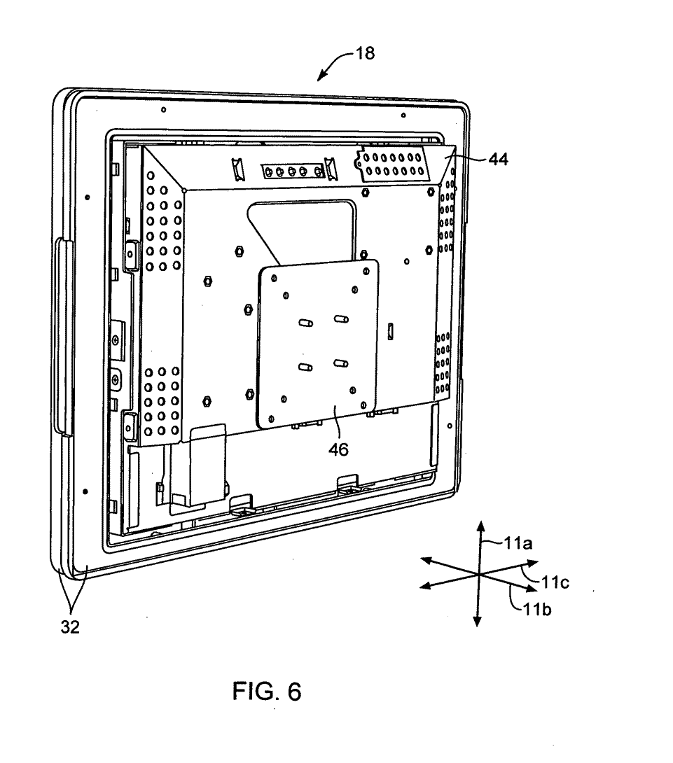

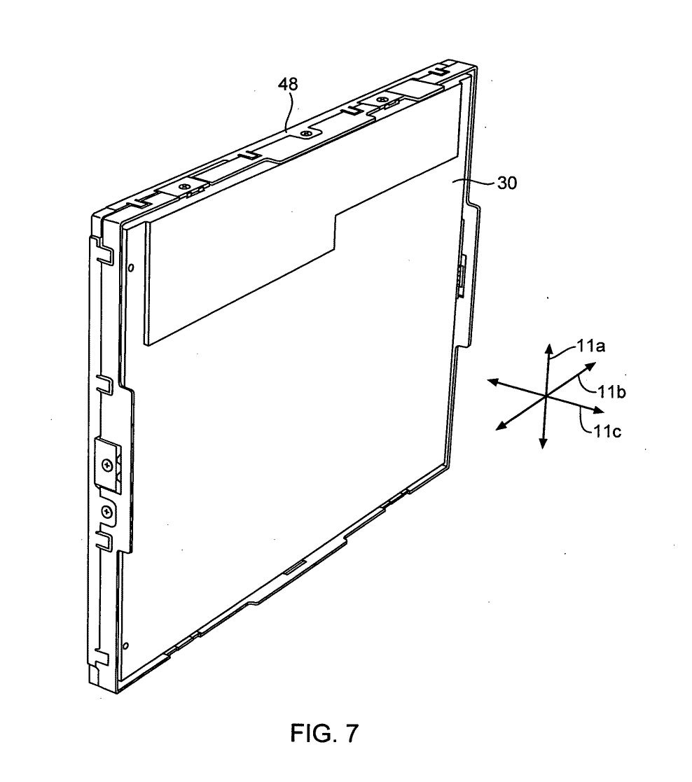

Referring now to FIGS. 6 and 7, a monitor 18 in accordance with the present invention may have any suitable structures facilitating securement thereof to an extension member 38, mounting plate 36 or the like as illustrated in FIGS. 4 and 5. For example, a monitor 18 may include a shield 44 extending to connect or engage a mounting plate 46, which may extend to engage an extension member 36. Additionally, a monitor 18 may include a mounting rim 48 or clip 48 surrounding the screen 30 portion of a monitor 18.

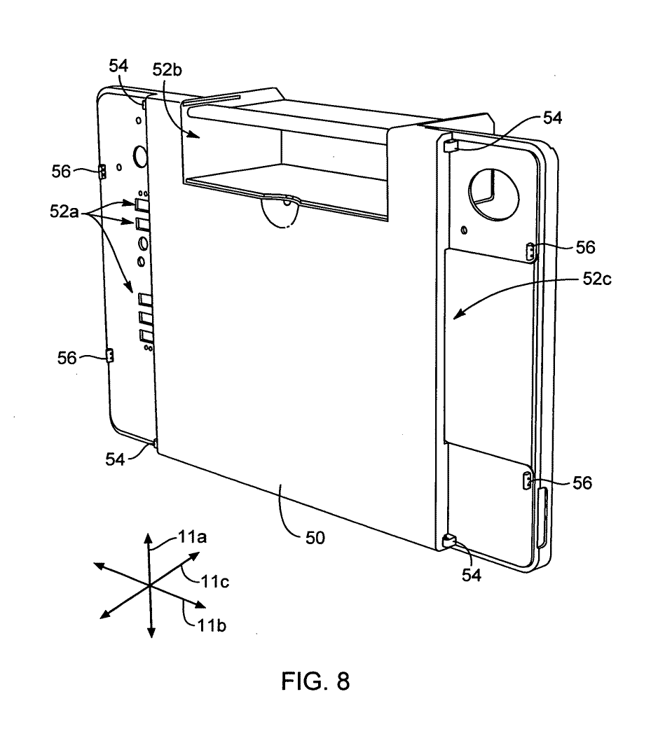

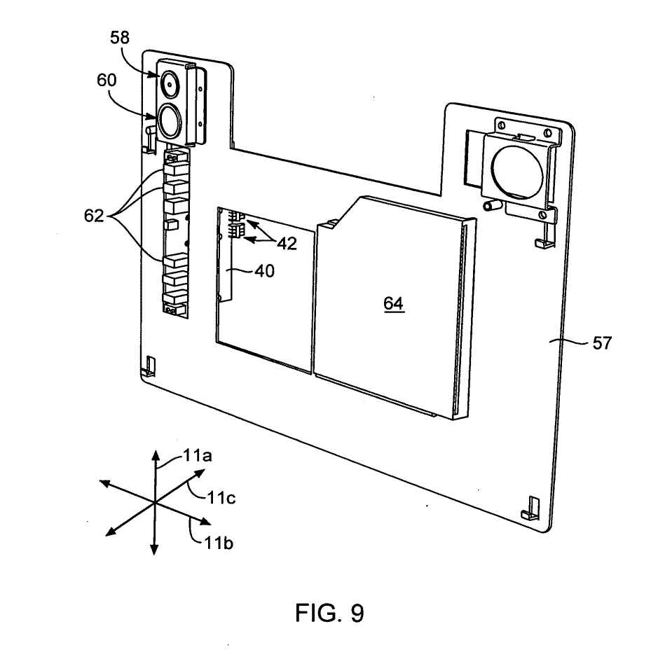

Referring to FIGS. 8 and 9, a user interface 20 may include a cover extending thereover. The cover 50 may include one or more apertures 52. The apertures may provide locations for switches, ports, speakers, or the like. In one embodiment, a cover 50 may include an aperture 52b sized to store selected items therein.

In certain embodiments, a cover 50 may include one or more hinges 54 for engaging doors 34 shown in FIG. 3. A cover 50 may also include one or more latches 56 for engaging the doors 34 and maintaining the doors 34 in a closed position. In selecting the embodiments, behind a cover 50 may be a mounting board 57 securing the various components of a user interface 20 in accordance with the present invention.

For example, in one embodiment illustrated in FIG. 9, a mounting board 57 may secure or mount a switch 58 powering the system 10. A board 57 may secure other switches 60 as necessary such as a biometric or fingerprint switch. A board 57 may also secure various port mechanisms permitting connection of various devices or the transferred data between devices and a system 10 in accordance with the present invention. For example, a board 57 may include one or more USB ports 62. Other devices may be secured to a board as necessary or desired. For example, in one embodiment a CD or DVD drive 64 may be secured to a board 57 in accordance with the present invention.

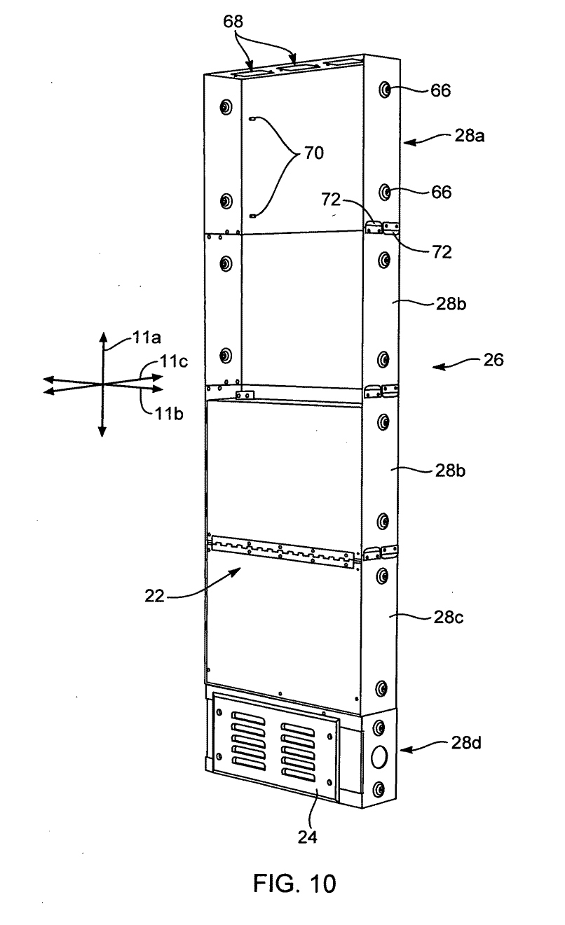

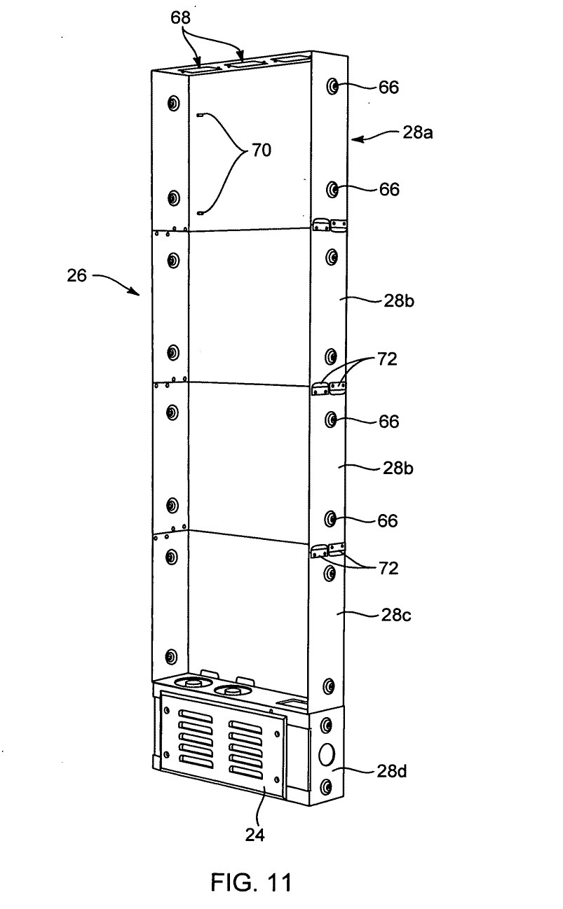

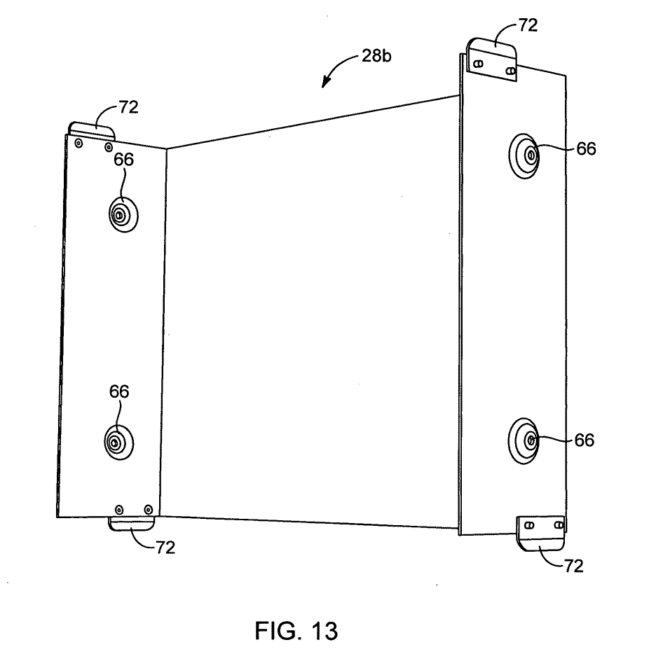

Referring now to FIGS. 10-14, the various sections 28 of a housing 26 in accordance with the present invention may include one or more apertures 66. The apertures 66 may be positioned to permit fasteners to secure the various sections 28 to neighboring or adjacent wall studs 14. In one embodiment, the apertures 66 may be somewhat conical in shape. This shape may permit the majority of the sections 28 to be more easily fit between the studs 14, with only the material surrounding the apertures 66 extending to contact the studs 14.

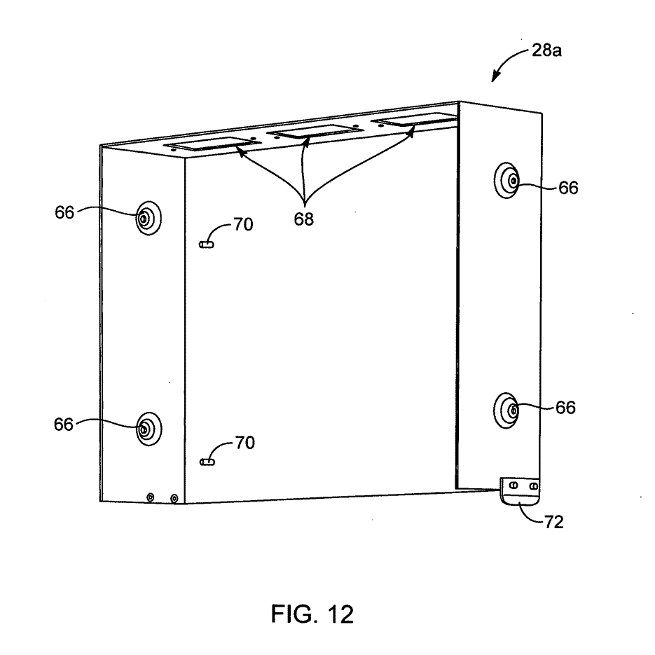

A top section 28a of a housing 26 in accordance with the present invention may include one or more apertures 68. The apertures 68 may provide fluid communication between an area inside the housing 26 and a location within a wall 12 or outside of the housing 26. Additionally, the apertures 68 may provide a location for cables, wires, or the like to pass, thereby connecting the systems of a building to a system 10 in accordance with the present invention. An upper section 28a may also include one or more extension mechanisms 70 as shown in FIG. 12. Such mechanisms 70 may be used to facilitate securement of a monitor 18, user interface 20, or the like to the housing 26.

In selected embodiments, it may be desirable to facilitate or insure alignment between the various sections 28 of a housing 26. That is, as the various sections 28 are aligned and secured to the studs 14, it may be desirable to ensure that one section 28 firmly and properly engages or aligns with a corresponding or adjacent section 28. To provide such alignment, sections 28 in accordance with the present invention may include one or more alignment mechanisms 72.

An alignment mechanism 72 may extend from one section 28 to engage or abut an adjacent section 28. Similarly, the adjacent section 28 may have an alignment mechanism 72 extending to engage or abut the other section 28. Accordingly, the engagement mechanisms 72 may provide mutual engagement between neighboring or adjacent sections 28.

In selected embodiments, an intermediate section 28b in accordance with the present invention may be used multiple times within a housing 26. Accordingly, by repeating an installation of an intermediate section 28b the space between a vent section 28d and an upper or top section 28a may be space or increased (i.e., the longitudinal 11a length of a housing 26 may be varied).

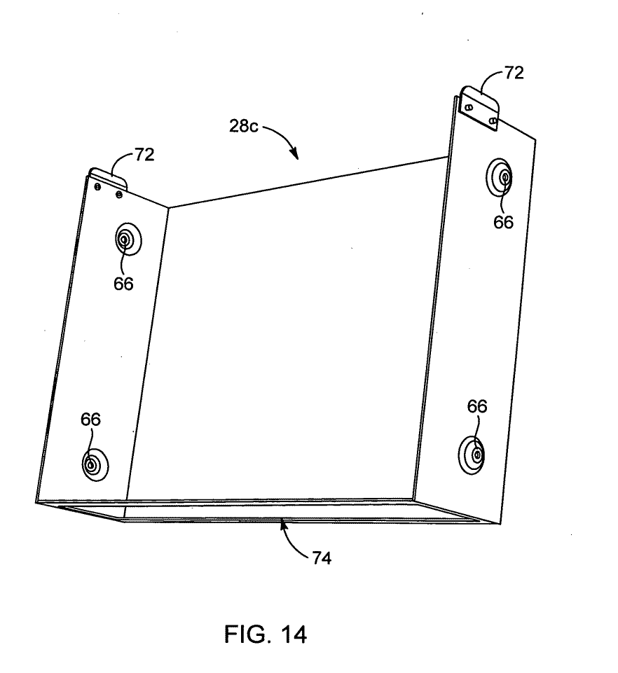

In selected embodiments, a lower section 28c may include an aperture 74. An aperture 74 as illustrated in FIG. 14 may provide fluid communication between a lower section 28c and a ventilation section 28d. Additionally, an aperture 74 may permit cables or other wiring to pass between the various sections 28c, 28d of a housing 26.

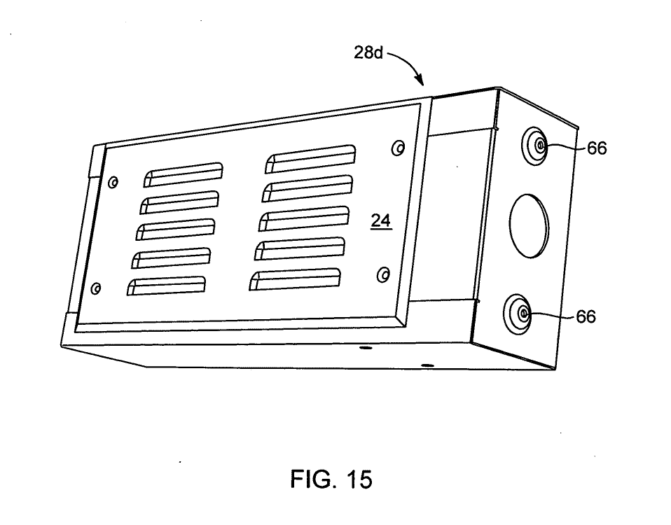

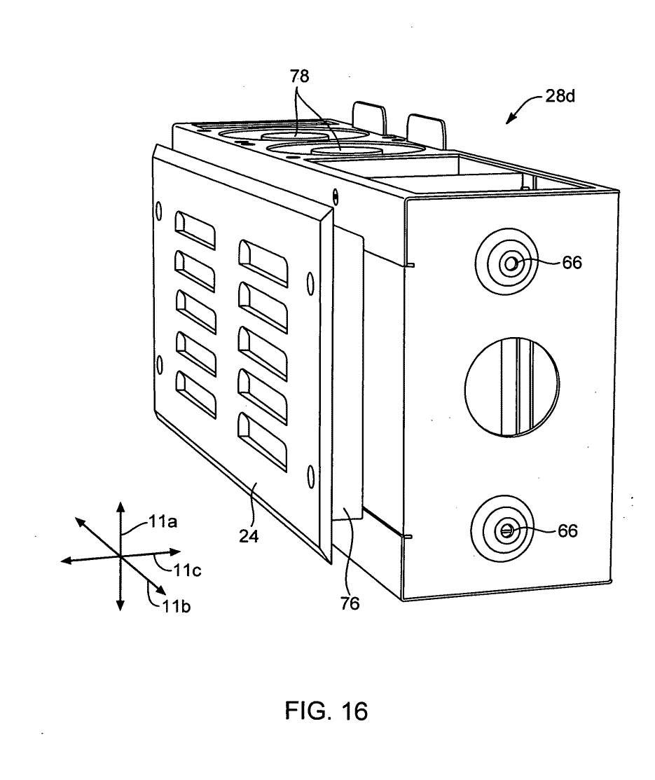

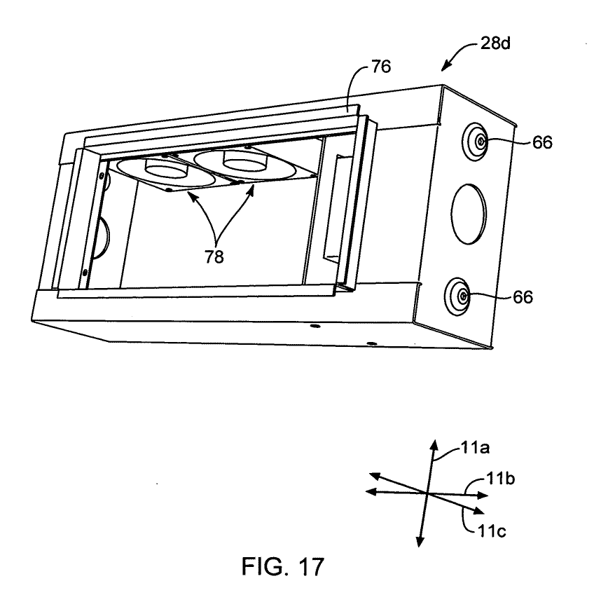

Referring to FIGS. 15-18, a ventilation section 28d may include an extension flange 76. An extension flange 76 may extend from the ventilation section 28d, through a wall covering 16, to engage a ventilation cover 24. In selected embodiments, a ventilation section 28d may include one or more fans 78. In certain embodiments, the fans 78 may draw air down through the housing 26 and out the ventilation section 28d or vent cover 24. Alternatively, one or more fans 78 may draw air in through the ventilation cover 24a and force it up through the housing 26. The fan or fans 78 may be sized to provide adequate cooling of the components (e.g., processing unit 22) of a system 10 in accordance with the present invention.

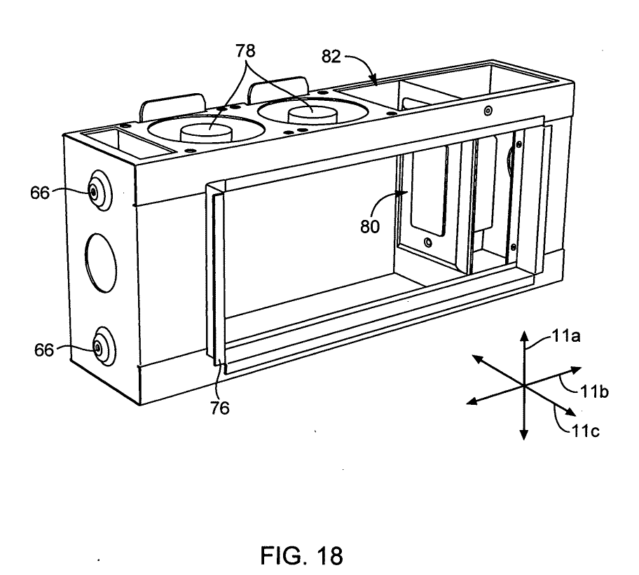

In selected embodiments, a ventilation section 28d may include an electrical power outlet 80 as shown in FIG. 18. For example, a ventilation section 28d may include a power outlet 80 supporting engagement with one or more power plugs. Positioned adjacent an outlet 80 may be an aperture 82. The aperture 82 may permit cabling or wires to pass into the ventilation section 28d to engage the outlet 80. In certain embodiments, an outlet 80 may be connected to the electrical power system of a building. The various components of a system 10 in accordance with the present invention may then receive their electrical power through connections to the outlet 80 (e.g., plugging into the outlet 80).

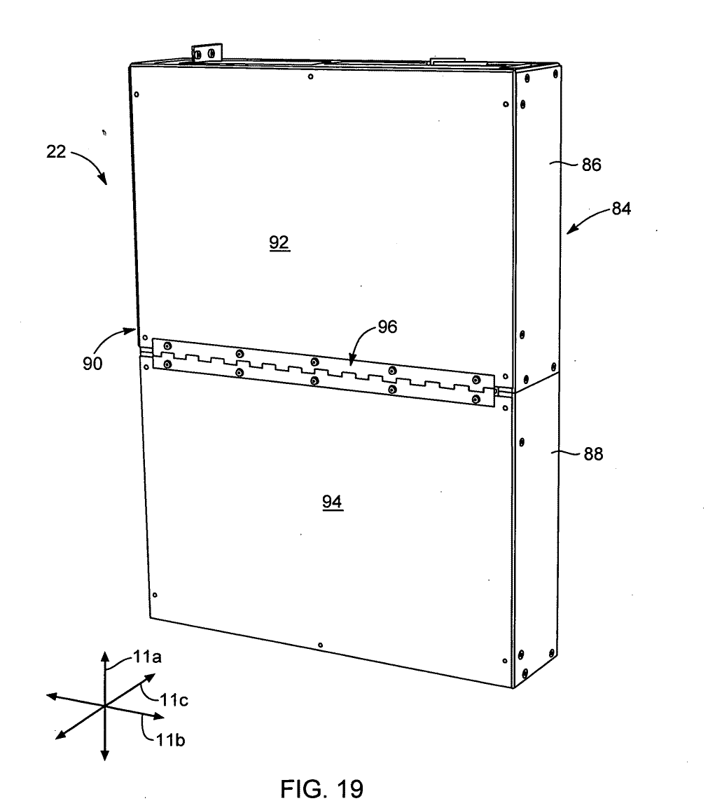

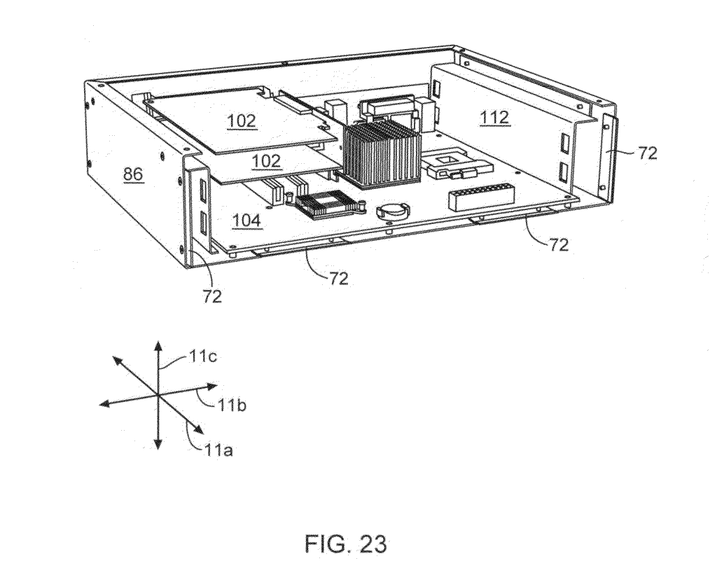

Referring to FIGS. 19-24, in selected embodiments, a processing unit 22 may include an exterior case 84. A case 84 may include a first half 86 and a second half 88. A removable cover 90 may connect the first half 86 to second half 88. A cover 90 may itself have a first half 92 corresponding to the first half 86 of the case 84. Similarly, a cover 90 may include a second half 94 corresponding to the second half 88 of the case 84.

A cover 90 may include a hinge 96 connecting the first half 92 to the second half 94. Accordingly, a case 84 in accordance with the present invention may be able to bend or fold (e.g., at or near a midpoint). The ability to fold a processing unit 22 in accordance with the present invention may facilitate its installation through apertures that are generally smaller than its length. That is, the unit 22 may be installed without cutting unnecessarily large apertures in a wall covering 16.

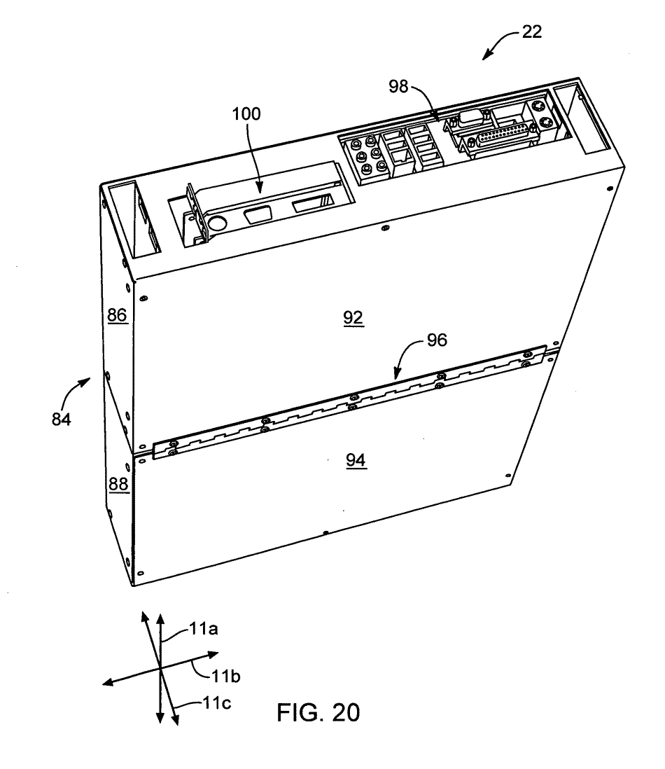

An upper end of a case 84 may include an aperture exposing an array 98 of ports or connection mechanisms as shown in FIG. 20. The ports may facilitate communication of data between a processing unit and a user interface 20 or a monitor 18 or some combination thereof. An upper end of a case 84 may also include an aperture 100 sized to support installation of one or more cards 102.

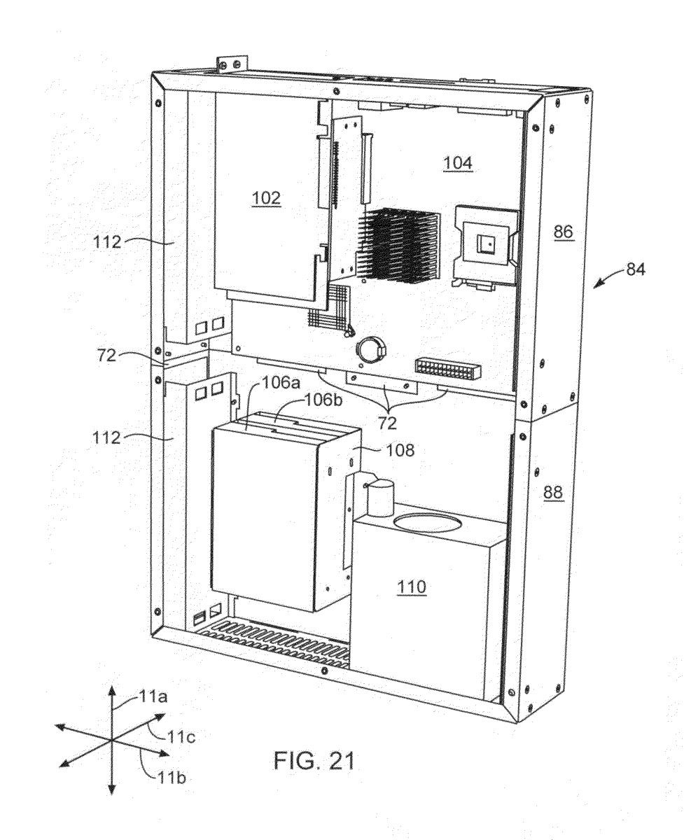

In selected embodiments, a mother board 104 may be positioned within a first half 86 of a case 84 in accordance with the present invention as shown in FIGS. 21-23. The mother board 104 may be positioned such that the case 84 may flex at the hinge 96 without requiring bending or flexing of the mother board 104.

In selected embodiments, one or more hard drives 106 may be secured within a hard drive bracket 108 positioned within a second half 88 of a case 84. For example, in the illustrated embodiment a first hard drive 106a and a second hard drive 106b are both secured within a hard drive bracket 108. In selected embodiments, a case 84 in accordance with the present invention may contain a power supply 110. For example, in the illustrated embodiment a power supply 110 is positioned within the second half 88 of a case 84.

In selected embodiments, a case 84 may include one of more cable guides 112. For example, a first half 86 may include one cable guide, while a second half 88 may include a second cable guide or pair of cable guides 112. A cable guide 112 in a first half 86 may be aligned with a cable guide 112 in a second half 88 of a case 84. Accordingly, cables passing through a case 84 may be protected.

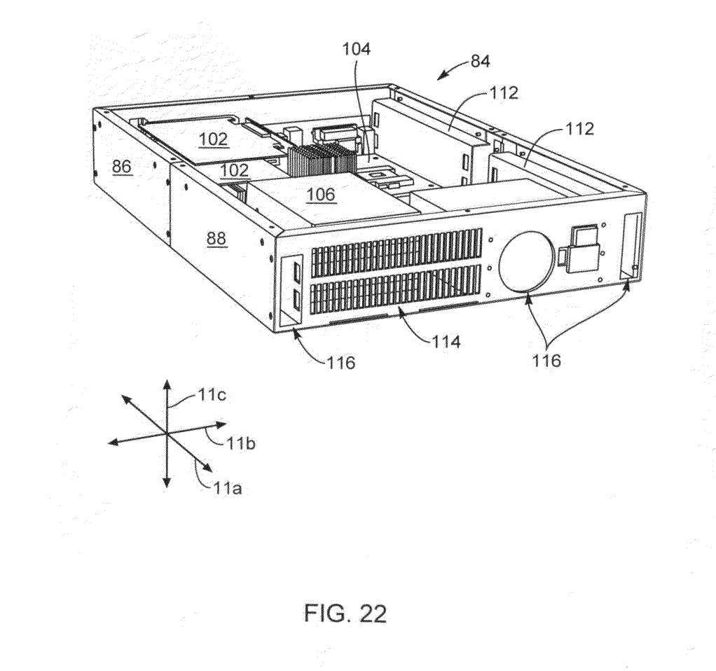

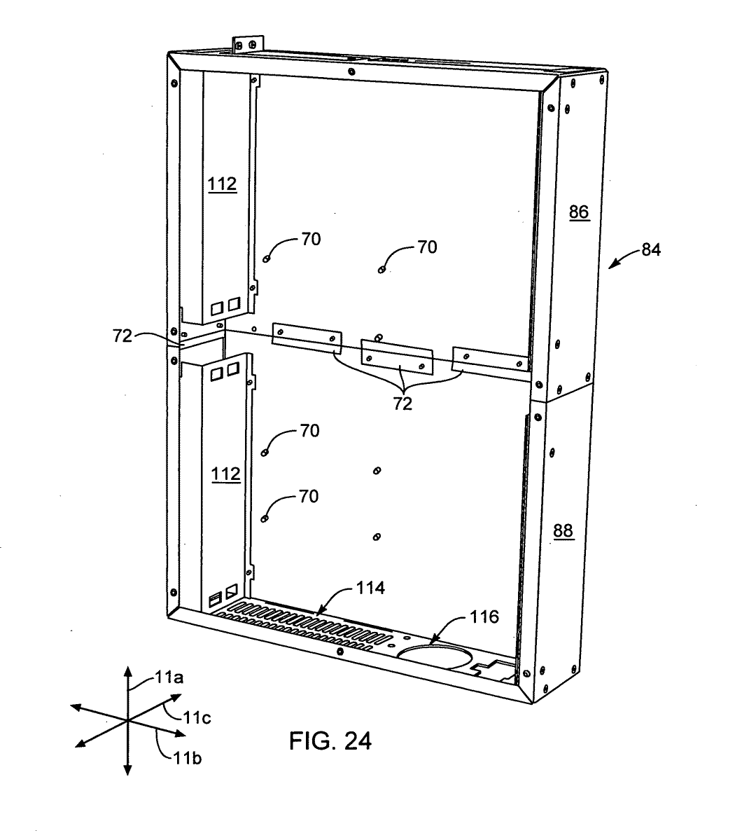

In selected embodiments, a bottom end of a case 84 in accordance with the present invention may include various apertures 114, 116 as shown in FIGS. 22 and 24. For example, in selected embodiments one or more apertures 114 for improving ventilation through a processing unit 22 may be included. In one embodiment, a ventilation aperture 114 or series of apertures 114 may be positioned above or adjacent the fan or fans 78 of a ventilation section 28d. Other apertures 116 may be positioned to receive cabling or the like passing out of or into a processing unit 22 or other components of a system 10 in accordance with the present invention.

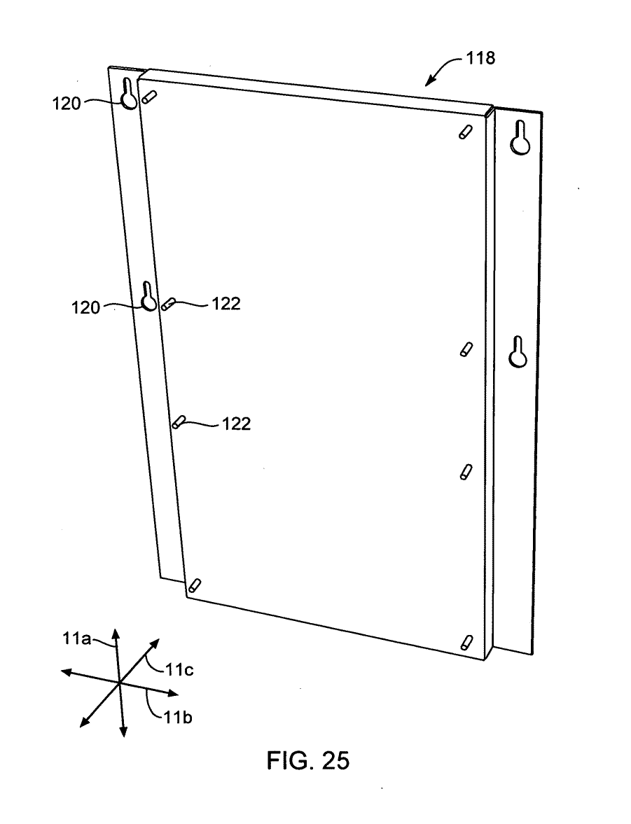

Referring to FIG. 25, in selected embodiments, a mounting plate 118 may be secured within a housing 24. In selected embodiments, a mounting plate 118 may provide an interface between the engagement mechanism 70 of an upper section 28a and the mounting plate 36 or plates 36 (as shown in FIG. 4) of a monitor 18, user interface 20, or the like. In selected embodiments, a mounting plate 118 may include apertures 120 for engaging the engagement extensions 70 or engagement mechanisms 70 of an upper section 28a. A mounting plate 118 may also include various extensions 122 positioned to engage corresponding apertures in the mounting plate 36 of the monitor 18 or user interface 20.

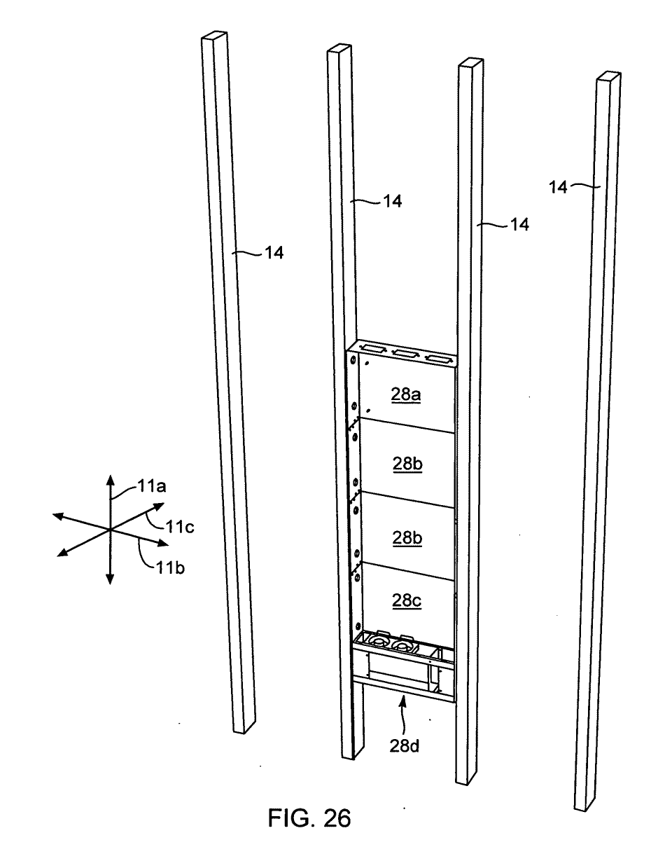

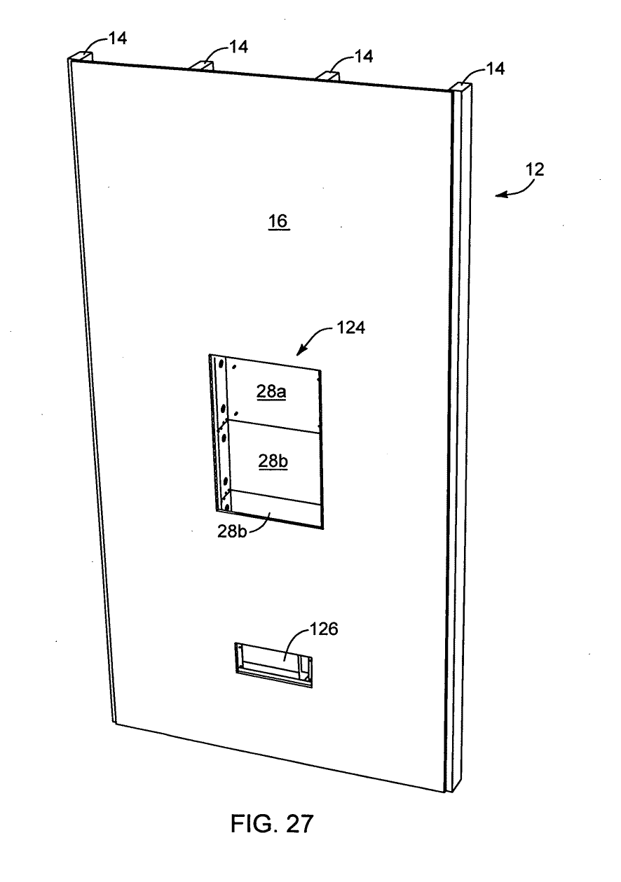

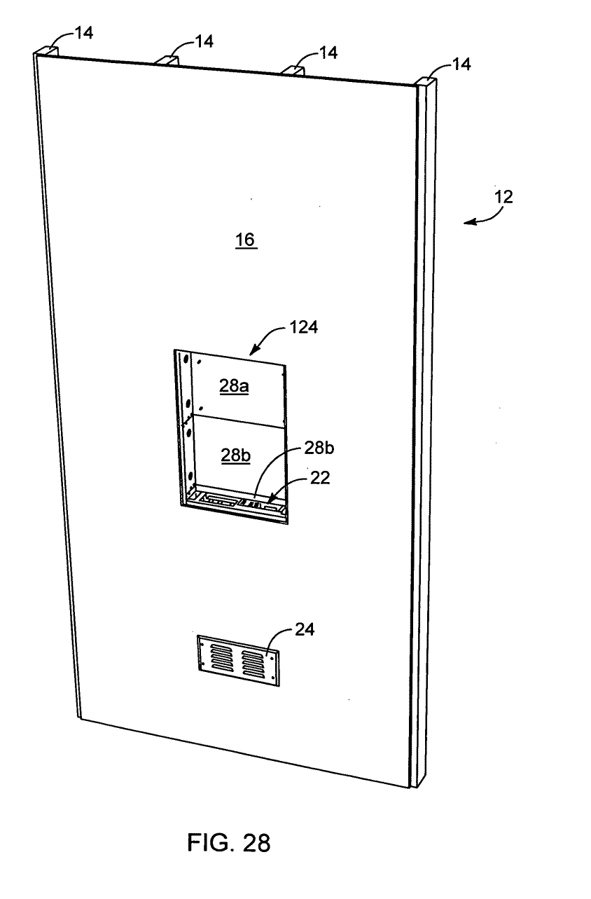

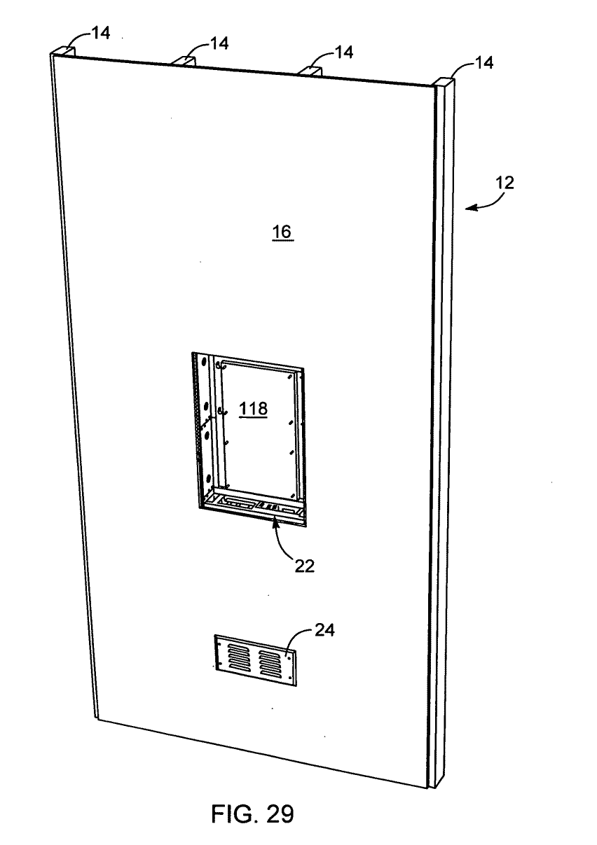

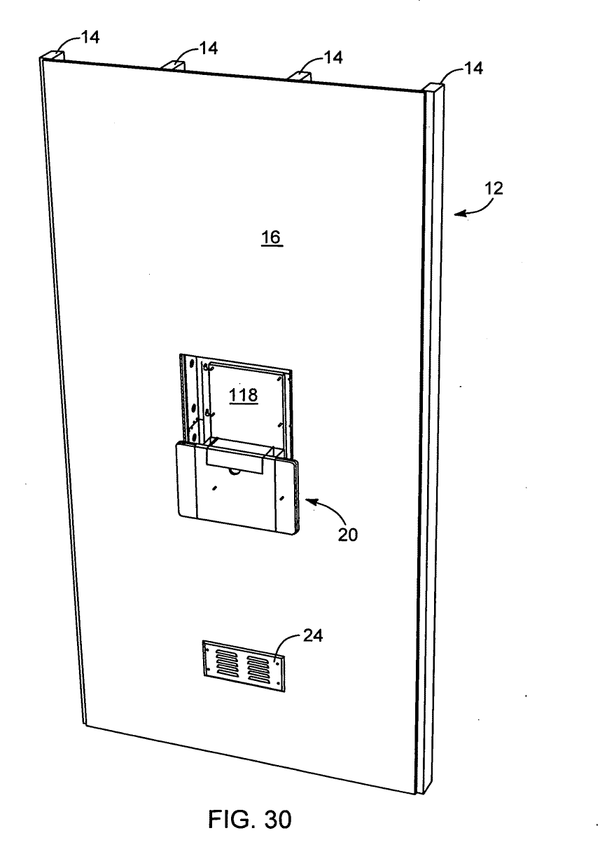

Referring to FIGS. 26-30, installation of a system 10 in accordance with the present invention may begin before wall coverings 16 have been installed. For example, the various sections 28 of a housing 26 may be installed after vertical studs 14 have been installed. In selected embodiments, a lateral width of the various sections 28 may correspond to a standard width or distance between vertical studs 14. For example, wall studs 14 are generally placed 16 inches on center from adjacent studs 14. Accordingly, sections 28 of a housing 26 may be sized to fill the space between adjacent studs 14 whatever the space is.

Once the sections 28 are installed, cabling from various systems (e.g., lighting, HVAC, entertainment, security, etc.) within a building may be routed to the housing 26 (e.g., through apertures 68). Upon completion of wire routing, wall coverings 16 such as drywall 16 may be applied over a housing 26. In certain embodiments, two apertures 124, 126 may be cut in the wall covering 16. For example, a first or upper aperture 124 may be cut through a wall covering 16 to expose a portion of the housing 26 (e.g., an upper section 28a and perhaps some portion of one or more intermediate sections 28b of a housing 26). Similarly, a lower aperture 126 may be cut through a wall covering 16 to expose the extension flange 76 of a ventilation section 28d.

Next, a processing unit 22 may be installed. In selected embodiments installation of a processing unit 22 may begin with insertion of a second half 88 of a case 84 into a cavity defined by the sections 28 and the wall covering 16. In one embodiment, a hinge 96 may be utilized to bend a first section 86 of the case 84 towards an installer and out the aperture 124. Accordingly, once the second section 88 of a case has been lowered into the housing 26 a sufficient distance, then the upper or first half 86 of a case 84 may be pivoted into vertical alignment with the second half 88 and similarly lowered into the housing 26. In selected embodiments, a processing unit 22 may be lowered within the housing until it contacts the bottom of a lower section 28c. Any connections between a processing unit 22 and a ventilation unit (e.g., outlet 80 of a ventilation unit 28d) may be affected prior to installing a ventilation cover 24.

A mounting plate 118 may then be installed within a housing 26. With a mounting plate 118 installed, a user interface 20, monitor 18, and the like may be installed and substantially fill and cover the upper aperture 124 in the wall covering 16.

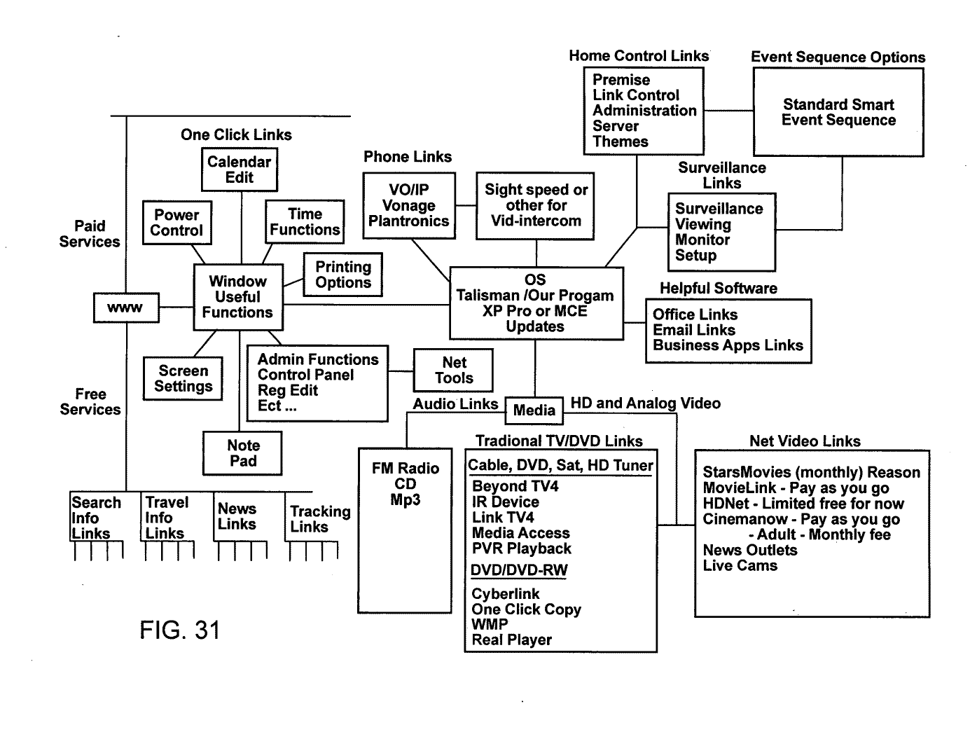

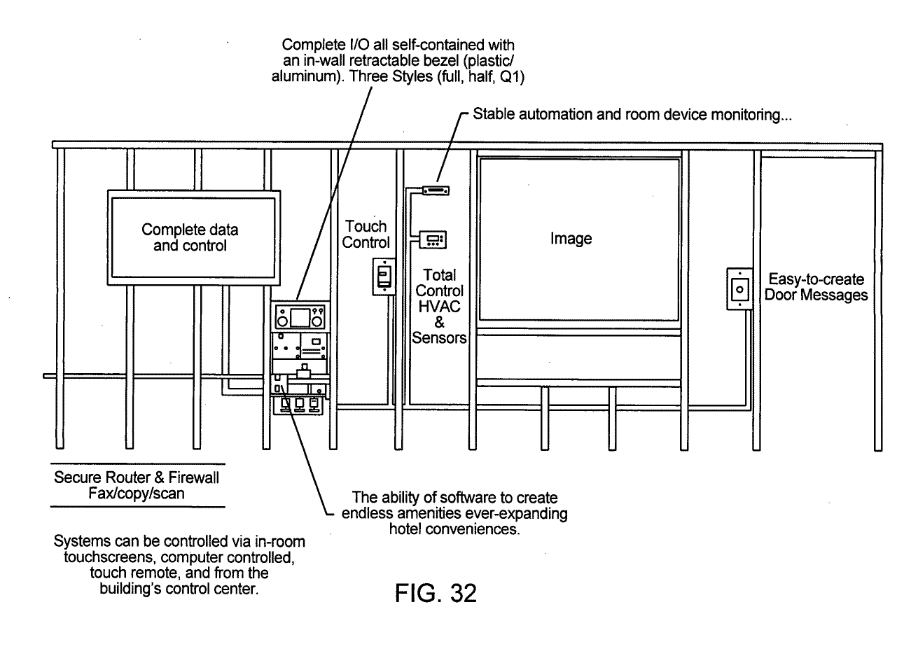

Referring to FIGS. 31 and 32, various systems of a building may be connected to a system 10 in accordance with the present invention. FIG. 31 illustrates various hardware and/or software components that may be supported by a system in accordance with the present invention. FIG. 32 illustrates one embodiment of the functionality and connections of a system in accordance with the present invention installed in a hotel environment.

The present invention may be embodied in other specific forms without departing from its fundamental functions or essential characteristics. The described embodiments are to be considered in all respects only as illustrative, and not restrictive. All changes which come within the meaning and range of equivalency of the illustrative embodiments are to be embraced within their scope.

1. A digital delivery system comprising:
a housing containing a group of electronic components, said electronic components operable to control a hardware network of the digital delivery system;
said housing including a back surface connected to multiple side walls, said housing sized to fit within a wall recess;
a wall-mounted cover unit positioned over a wall opening through which said housing is inserted into said wall recess;
a display device supported by the cover unit; and
means for interfacing with the digital delivery system.

2. The system of claim 1 wherein the hardware network includes one or more surveillance cameras, home appliances, telephones, intercoms, televisions or radios.

3. The system of claim 1 further comprising a face plate removably secured to said housing.

4. The system of claim 1 wherein the wall-mounted cover unit is mounted higher on a wall than a final position of the housing within the wall recess.

5. The system of claim 1 wherein the means for interfacing with the digital delivery system comprises touch screen technology implemented via said display device.

6. The system of claim 1 wherein the means for interfacing with the digital delivery system comprises a keyboard linked to said digital delivery system.

7. The system of claim 1 further comprising a shell inserted and mounted within the wall opening.

8. A digital delivery system comprising:
a housing containing a group of electronic components, said electronic components operable to control a hardware network of the digital delivery system;
said housing including a back surface connected to multiple side walls and a removable face plate, said housing sized to fit within a wall recess;
a wall-mounted cover unit positioned over a wall opening through which said housing is inserted into for positioning within;
a shell inserted and mounted within said wall opening, said shell operable to house certain network hardware;
a display device supported by the cover unit; and
a user interface.

9. The system of claim 8 wherein the hardware network includes one or more surveillance cameras, home appliances, telephones, intercoms, televisions or radios.

10. The system of claim 8 wherein the shell houses one or more CD readers and/or writers, DVD readers and/or writers, tape decks or floppy disc readers.

11. The system of claim 8 wherein the user interface comprises touch screen technology implemented via said display device.

12. The system of claim 8 wherein the user interface comprises a keyboard linked to said digital delivery system.

13. A method of installing a digital delivery system comprising:
creating an opening in a wall wherein said opening is sized to accommodate a digital delivery system housing, said wall opening at a vertical level to facilitate convenient operation of the digital delivery system by a user;
inserting the digital delivery housing and contained electronic components into said wall opening such that the housing can be positioned within a wall recess accessible via the wall opening;
connecting hardware and software devices to said electronic components contained in said housing; and
mounting a cover unit to the wall such that the cover unit conceals the wall opening and positioned housing.

14. The method of claim 13 further comprising creating an opening by cutting or punching the opening.

15. The method of claim 13 further comprising positioning a removable face plate on said housing.

16. The method of claim 13 further comprising mounting a shell in said wall opening prior to mounting the cover unit to the wall.

17. The method of claim 13 further comprising positioning the housing in a wall recess below the wall opening.

18. (canceled)
